(19) United States
(12) Patent Application Publication
(10) Pub. No.: US 2007/0098889 A1
(43) Pub. Date: May 3, 2007

(54) Vacuum film deposition method and system, and filter manufactured by using the same

(75) Inventors: Kouichi Nose, Hyogo (JP); Shinichi Yamabe, Hyogo (JP); Isao Tokomoto, Hyogo (JP); Takanobu Hori, Hyogo (JP); Atsushi Shozude, Hyogo (JP); Takahiko Kondo, Hyogo (JP)

Correspondence Address: MARSHALL, GERSTEIN & BORUN LLP, 233 S. WACKER DRIVE, SUITE 6300, SEARS TOWER, CHICAGO, IL, 60606, US

(73) Assignee: Shinmaywa Industries, Ltd., Hyogo (JP)

(21) Appl. No.: 10/570,449

(22) PCT Filed: Aug. 30, 2004
(86) PCT No.: PCT/JP04/12878

§ 371 Date: Oct. 30, 2006

(30) Foreign Application Priority Data
Sep. 5, 2003 (JP) 2003-314459

(51) Int. Cl. C23C 16/00; B05D 3/00

(52) U.S. Cl. 427/248.1; 427/294; 118/726

(57) ABSTRACT

A vacuum film deposition method comprises the steps of mounting a substrate on a substrate holder (6a) that is disposed in a vacuum chamber (1) and is provided with a passage (7f), (7g), and (7j) in which predetermined heat medium flows; maintaining an inside of the vacuum chamber substantially in vacuum state; evaporating evaporation materials from two or more evaporation sources in the inside of the vacuum chamber; and diffusing the evaporated evaporation materials in the inside of the vacuum chamber in a predetermined order; and depositing the diffused evaporation materials on a deposition surface of the substrate, thereby forming a multi-layered film made of the evaporation materials on the deposition surface of the substrate; wherein an antifreezing fluid is used as the predetermined heat medium flowing in the passage of the substrate holder.

### TECHNICAL FIELD

The present invention relates to a vacuum film deposition method and system for depositing a multi-layered film on a substrate in a vacuum chamber, and an optical filter manufactured by using the same.

### BACKGROUND ART

Hitherto, various vacuum film deposition systems have been employed as apparatuses for manufacturing optical filters used for the purpose of transmitting light in predetermined wavelength band by forming a multi-layered film on the surface of a substrate such as glass plate.

As a vacuum film deposition system, for example, an ion plating system is suitably used. The ion plating system has a vacuum chamber capable of maintaining its inside substantially in vacuum state. The vacuum chamber has two or more evaporation sources for evaporating film materials at the bottom thereof, and opposite to the evaporation sources, a substrate holder is disposed. At a center region of the back of the substrate holder, a rotational shaft is provided by an insulating board, and the rotational shaft is penetrates the ceiling wall of the vacuum chamber and is connected to a rotation drive device disposed in the upper part of the vacuum chamber. That is, the substrate holder is rotatably supported by the rotational shaft and rotation drive device in the vacuum chamber. An annular contact element is buried in the outer periphery of a contact area of the insulating board and the substrate holder. This contact element is electrically connected to the substrate holder. A carbon brush contacts with the contact element, and the carbon brush is connected to a radio-frequency power source for supplying radio-frequency power to the substrate holder, and a direct-current power source for applying a bias voltage. To protect the rotational shaft and the rotation drive device, they are entirely surrounded by part of the vacuum chamber and the housing.

In this ion plating system, a substrate such as glass plate is mounted on the substrate holder, and then the rotation drive device is operated to rotate the substrate, and a radio-frequency power source and a direct-current power source are turned on. As a result, radio-frequency power and bias voltage are applied to the rotating substrate holder from the contact element, that is, the carbon brush. Consequently, a radio-frequency electric field is generated in the interior of the vacuum chamber, and a bias electric field is generated between the substrate holder and the vacuum chamber. Thereafter, electron beams are emitted from an electron gun toward the two or more evaporation sources. By emission of electron beams, the temperature of film materials disposed on the evaporation sources is raised, causing the film materials to be evaporated. When the evaporated film materials are diffused into the vacuum chamber in a predetermined order, the diffused film materials are sequentially excited by the plasma generated by the radio-frequency electric field, and the excited film materials are accelerated by the bias electric field, and impinged and adhered to the surface of the substrate in a predetermined order. Finally, a thin film having strong adhesivity is formed on the substrate to have a predetermined layered structure. That is, a multi-layered film having a predetermined optical characteristic is deposited on the substrate.

In the conventional ion plating system operating in this manner, the substrate such as glass plate on which the multi-layered film having predetermined optical characteristic is deposited is disposed opposite to the evaporation sources for evaporating the film materials. That is, a space is formed between the substrate and evaporation sources so that the film materials diffused from the evaporation sources may reach the substrate with being disturbed. Accordingly, when the temperature of evaporation sources is raised by emission of electron beams from the electron gun, the temperature of the substrate is raised extremely by radiation heat from the heated evaporation sources. As a result of this temperature rise, the substrate may be deformed or deteriorated, and the optical characteristic of the film deposited on the substrate may be degraded.

To avoid the problem that the temperature of the substrate rises extremely by radiation heat from the evaporation sources heated by the electron beams, a substrate cooling structure is proposed for preventing the temperature rise of the substrate by forming a passage of a coolant such as cooling water inside the substrate holder and flowing the coolant such as the cooling water in the passage at a predetermined flow rate (see, for example, Japanese Patent Application Laid-Open No. 2001-212446, FIG. 1).

Thus, by forming a passage of the coolant such as cooling water inside the substrate holder for holding the substrate and flowing the coolant such as cooling water in the passage at a predetermined flow rate, the substrate holder is cooled by the coolant, and the substrate such as glass plate is cooled below a predetermined temperature, and hence distortion or deformation of substrate may be effectively prevented. That is, the problem of degradation of optical characteristic of the thin film deposited on the substrate can be solved.

However, the ion plating system in which the passage of the coolant such as cooling water is formed in the substrate holder and the coolant such as cooling water is flowed in the passage at a predetermined flow rate is effective when the substrate is formed of glass plate or other material of high heat resistance, but is not effective when the substrate is made of resin or other material low in heat resistance. In particular, it is not effective when the multi-layered film includes a number of layers of 30 layers or more that are stacked on the deposition surface of substrate. The reason is as follows. In the case where temperature of evaporation sources is raised by emission of electron beams, and temperature of substrate is raised by radiation heat from the heated evaporation sources, if attempted to cool the substrate by the coolant such as cooling water, the substrate temperature may exceed the heat resistant temperature of the resins forming the substrate. Besides, as the number of layers of the multi-layered film deposited on the substrate is increased, the film forming time becomes longer, and heating of substrate by radiation heat is promoted, which further increases the risk of the substrate temperature exceeding the heat resistant temperature of the resins for forming the substrate.

That is, in the conventional ion plating system in which the passage of the coolant such as cooling water is formed in the substrate holder and the coolant such as cooling water is flowed in the passage at a predetermined flow rate, applicable substrates are limited to substrates made of heat resistant materials such as glass plate (resin substrate is not be able to be used), and when the resin substrates are used, the number of layers to be formed on the substrate is limited.

### DISCLOSURE OF PRESENT INVENTION

The present invention has been made to solve the problem, and it is hence an object thereof to provide a vacuum film deposition method and system capable of forming a multi-layered film including a number of layers on a deposition surface of a resin substrate or a substrate having a resin layer in at least a surface layer thereof, and an optical filter manufactured by using the same.

To achieve the above mentioned object, the vacuum film deposition method and system of present invention are configured in such a manner that, in the vacuum film deposition method comprising the steps of mounting a substrate on a substrate holder that is disposed in a vacuum chamber and is provided with a passage in which predetermined heat medium flows; maintaining an inside of the vacuum chamber substantially in vacuum state; evaporating evaporation materials from two or more evaporation sources in the inside of the vacuum chamber; diffusing the evaporated evaporation materials in the inside of the vacuum chamber in a predetermined order; and depositing the diffused evaporation materials on a deposition surface of the substrate, thereby forming a multi-layered film made of the evaporation materials on the deposition surface of the substrate, an antifreezing fluid is used as the predetermined heat medium flowing in the passage of the substrate holder. In such a configuration, since the temperature of the substrate holder is set to a freezing point or lower by using the antifreezing fluid, the resin that is low in heat resistant temperature can be used as the substrate on which the multi-layered film is formed.

The antifreezing fluid used as the predetermined heat medium is controlled to have a temperature in a temperature range of −5° C. or higher to +30° C. or lower. In such a configuration, since the temperature of the substrate holder is adjustable in the temperature range of −5° C. or higher to +30° C. or lower, the temperature of the substrate is optimally adjusted during formation of the films.

The antifreezing fluid used as the predetermined heat medium when mounting or dismounting the substrate on or from the substrate holder is controlled to have a temperature in a temperature range of ±0° C. or higher to +30° C. or lower. In such a configuration, since the temperature of the substrate is set to a temperature substantially equal to a room temperature when mounting and dismounting the substrate on and from the substrate holder, water condensation on the substrate is prevented.

The antifreezing fluid used as the predetermined heat medium in a period until the inside of the vacuum chamber is held substantially in the vacuum state is controlled to have a temperature in a temperature range of ±0° C. or higher to +30° C. or lower. In such a configuration, since the temperature of the substrate is set to a temperature substantially equal to the room temperature, water or the like adsorbed onto the surface of the substrate is effectively removed during a process for evacuating the inside of the vacuum chamber to the substantially vacuum state.

The antifreezing fluid used as the predetermined heat medium when depositing the multi-layered film on the deposition surface of the substrate in the inside of the vacuum chamber is controlled to have a temperature in a temperature range of −5° C. or higher to ±0° C. or lower. In such a configuration, since the substrate is cooled by the antifreezing fluid, temperature rise due to radiation heat from the evaporation source is prevented.

A vacuum film deposition method comprises the steps of mounting a substrate on a substrate holder that is disposed in a vacuum chamber and is provided with a passage in which predetermined heat medium flows; maintaining an inside of the vacuum chamber substantially in vacuum state; evaporating evaporation materials from two or more evaporation sources in the inside of the vacuum chamber; diffusing the evaporated evaporation materials in the inside of the vacuum chamber in a predetermined order; and depositing the diffused evaporation materials on a deposition surface of the substrate, thereby forming a multi-layered film made of the evaporation materials on the deposition surface of the substrate; wherein the passage includes one passages and opposite passages that are arranged radially, and the multi-layered film is formed on the deposition surface of the substrate while flowing the predetermined heat medium into the one passage from an end portion of the substrate holder toward a center portion of the substrate holder, and flowing the predetermined heat medium into the opposite passage from the center portion of the substrate holder toward the end portion of the substrate holder. In such a configuration, the end portion of the substrate holder that tends to increase its temperature is efficiently cooled during film formation. In addition, since an in-plane temperature distribution of the substrate holder is improved, the optical characteristic of the multi-layered film such as an infrared cut filter formed on the deposition surface of the substrate is improved.

A film deposition system comprises a vacuum chamber that maintains an inside thereof substantially in vacuum state; a rotational shaft rotatably penetrating through the vacuum chamber; a heat medium supply unit connected to a heat medium supply passage in which a predetermined heat medium flows; a substrate holder fixed to an end portion of the rotational shaft, for holding the substrate having the passage in which the predetermined heat medium flows; and two or more evaporation sources including evaporation materials deposited to form a multi-layered film on a deposition surface of the substrate held on the substrate holder; wherein the rotational shaft has a groove formed to extend over an entire circumference of an outer periphery, the groove is connected to the passage of the substrate holder through a plurality of holes, and the groove is maintained in a sealed state with respect to the heat medium supply unit by a predetermined seal means. In such a configuration, the heat medium is supplied to the substrate holder from the periphery of the rotational shaft.

The film deposition system further comprises a tubular housing for accommodating a region of the rotational shaft in which the groove is provided; wherein a penetrating hole forming the heat medium supply unit is formed in a region of an inner peripheral surface of the housing that corresponds to the groove of the rotational shaft, and wherein a seal member is disposed between the housing and the rotational shaft, and the groove is maintained in a sealed state with respect to the penetrating hole by the seal member. In such a configuration, the heat medium is supplied to the substrate holder from the periphery of the rotational shaft.

A vacuum film deposition method comprises the steps of: mounting a substrate on a substrate holder that is disposed in a vacuum chamber; maintaining an inside of the vacuum chamber substantially in vacuum state; evaporating evaporation materials from two or more evaporation sources in the inside of the vacuum chamber; diffusing the evaporated evaporation materials in the inside of the vacuum chamber in a predetermined order; and depositing the diffused evaporation materials on a deposition surface of the substrate, thereby forming a multi-layered film made of the evaporation materials on the deposition surface of the substrate; wherein the multi-layered film is formed on the substrate mounted on the substrate holder with a heat conductive adapter interposed between the substrate and the substrate holder. Also, a film deposition system comprises a vacuum chamber that maintains an inside thereof substantially in vacuum state; a substrate holder for holding a substrate in the inside of the vacuum chamber; and two or more evaporation sources including evaporation materials deposited to form a multi-layered film on a deposition surface of the substrate held on the substrate holder; wherein a heat conductive adapter for increasing heat conductivity between the substrate and substrate holder is disposed on a surface of the substrate holder on which the substrate is held. In such a configuration, since heat conductivity between the substrate holder and the substrate is improved, the temperature of the substrate is precisely controlled.

A contact area of the heat conductive adapter and the substrate per predetermined area decreases as the contact area is closer to an end portion of the substrate. In such a configuration since the heat conductivity from the substrate holder to the substrate is controlled according to the contact area, the temperature is made substantially equal at a center region and an end region of the resin lens when forming the multi-layered film on the surface of the resin lens.

An optical filter of the present invention comprises a resin layer in at least a surface layer of a substrate, and two types of thin films with different light refractive indices that are alternately stacked on the resin layer to form an alternate layer, wherein the alternate layer is comprised of the films of at least 30 layers. In such a configuration, since the optical filter includes the resin layer, the weight of the optical filter is reduced. In addition, the optical characteristic of the optical filter is improved.

These and other objects of present invention, as well as the features and advantages thereof will be more clearly disclosed in the following specific examples explained along with the accompanying drawings.

### BRIEF DESCRIPTION OF THE DRAWINGS

FIG. 1 is a view schematically showing a vacuum film deposition system in first embodiment of present invention.

FIG. 2 is a magnified view schematically showing a rotation drive unit of the vacuum film deposition system shown in FIG. 1.

FIGS. 3A and 3B are sectional views of a structure in which an infrared ray cut filter formed on a substrate, in which FIG. 3A is a schematic sectional view of structure of the infrared ray cut filter formed on a silicon wafer, and FIG. 3B is a schematic sectional view of structure of infrared ray cut filter formed on a resin lens.

FIG. 4 is a view vacuum film deposition system in second embodiment of present invention.

FIG. 5 is a magnified view schematically showing the rotation drive unit of the vacuum film deposition system shown in FIG. 4.

FIGS. 6A and 6B are schematic views of a heat conductive adapter, in which FIG. 6A is a plan view thereof, and FIG. 6B is a sectional view along line VI-VI of FIG. 6A.

FIGS. 7A and 7B are graphs schematically showing the optical characteristic of infrared ray cut filter, in which FIG. 7A shows the optical characteristic when the filter is comprised of 48 layers, FIG. 7B shows the optical characteristic when the filter is comprised of 40 layers, FIG. 7C shows the optical characteristic when the filter is comprised of 30 layers, and FIG. 7D shows the optical characteristic when the filter is comprised of 16 layers.

### BEST MODE FOR CARRYING OUT PRESENT INVENTION

The best mode for carrying out present invention is described below by referring to the accompanying drawings.

(First Embodiment)

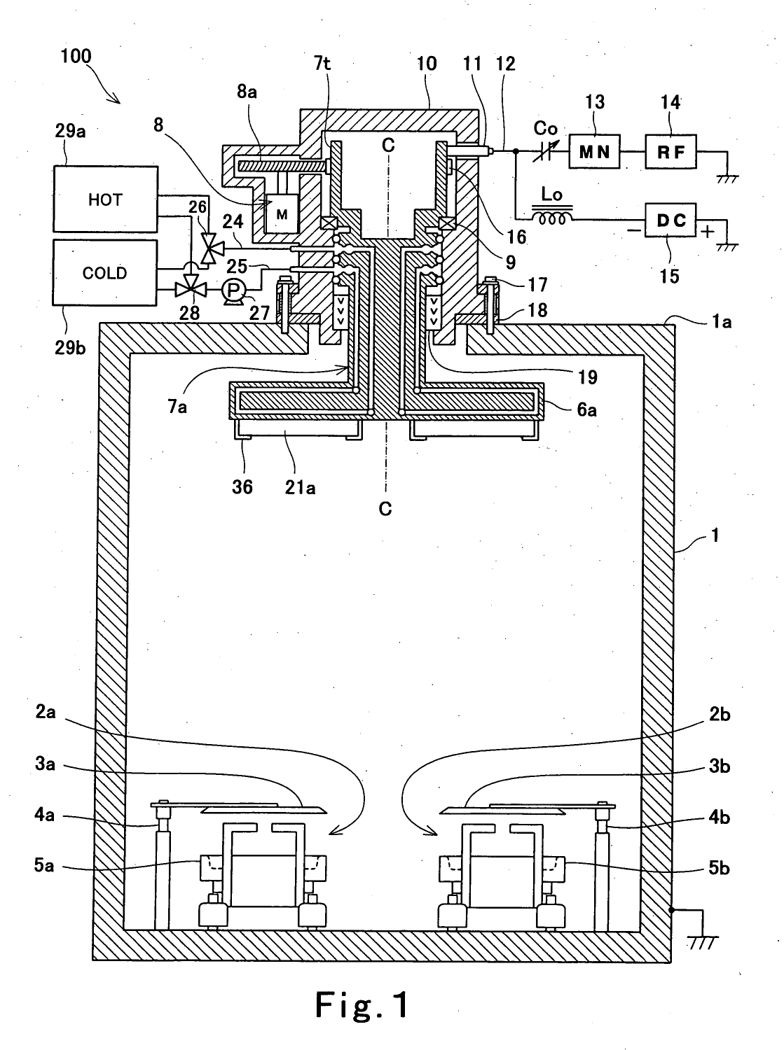

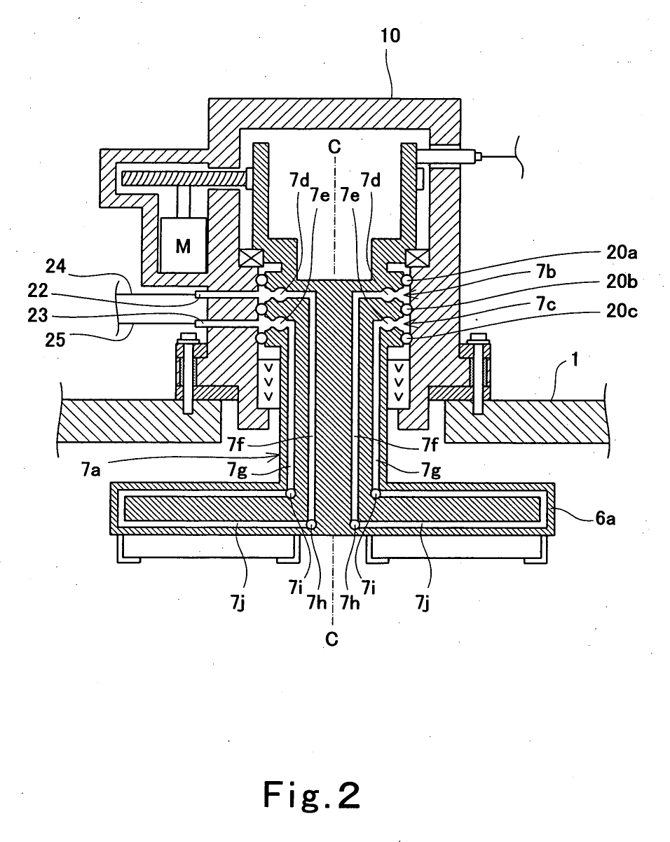

FIG. 1 is a view of vacuum film deposition system in first embodiment of present invention. FIG. 2 is a magnified view schematically showing a rotation drive unit of the vacuum film deposition system shown in FIG. 1. In this embodiment of present invention, an ion plating system is illustrated as the vacuum film deposition system.

Referring first to FIG. 1 and FIG. 2, the structure of ion plating system in the first embodiment of present invention is specifically described below.

As shown in FIG. 1, the ion plating system 100 comprises evaporation sources 2a and 2b for evaporating film materials disposed inside a vacuum chamber 1 made of conductive material, and a circular substrate holder 6a made of a conductive material that is disposed opposite to the evaporation sources 2a and 2b. A substrate 21a, a silicon wafer herein, is fixed on the substrate holder 6a on the substrate mounting surface of the substrate holder 6a by means of a predetermined fixing member 36. The evaporation sources 2a and 2b herein are comprised of a hearth 5a that disposes a film material, and an electron gun not shown disposed near the hearth 5a. Above the evaporation sources 2a and 2b, movable shutters 3a and 3b are pivotally disposed by means of rotational shafts 4a and 4b. On the back side of the substrate holder 6a, a columnar rotational shaft element 7a formed of conductive material extends. This rotational shaft element 7a is disposed to extend to outside through a wall 1a of the vacuum chamber 1. A portion of the rotational shaft element 7a protruding outward from the wall la (hereinafter called protruding portion) is rotatably supported on the housing 10 by a cross roller bearing 9 and an oil seal 19 so as to be driven to rotate by a rotation drive device 8. Since the oil seal 19 is disposed between the rotational shaft element 7a and the housing 10, the inside of the vacuum chamber 1 is kept in predetermined vacuum state.

As shown in FIG. 1 and FIG. 2, to apply a radio-frequency power and a direct-current power specified below to a current feeding ring 7t disposed on the outer circumference at the tip end of the protruding portion of the rotational shaft element 7a, a carbon brush 11 is disposed to contact directly the current feeding ring 7t as power transmission structure. This carbon brush 11 is fixed at a predetermined position on the housing 10 by a predetermined fixing means. As a result, the carbon brush 11 and the rotational shaft element 7a are held in electrically conducting state. Further, as shown in FIG. 1, the carbon brush 11 is connected to a direct-current blocking capacitor Co and a radio-frequency blocking choke coil Lo through a cable 12. The direct-current blocking capacitor Co is connected to a radio-frequency power source 14 through a matching circuit 13. The radio-frequency blocking choke coil Lo is connected to a direct-current power source 15. One terminal of the radio-frequency power source 14, positive terminal of the direct-current power source 15, and vacuum chamber 1 are respectively grounded. On the outer periphery of tip end of protruding portion of the rotational shaft element 7a, a cylindrical gear 16 to be engaged with a spur gear 8a of the rotation drive device 8 including, for example, motor M is mounted. By engagement between the spur gear 8a and the gear 16, the rotation drive device 8 operates to rotate the spur gear 8a, and rotation of the spur gear 8a causes the rotational shaft element 7a to rotate. When the rotation drive device 8 operates, the substrate holder 6a rotates, and the substrate 21a rotates about a rotation center c. The rotation drive device 8 is fixed at predetermined position of the housing 10 by a predetermined fixing method.

The housing 10 made of a conductive material is disposed so as to cover a part of the carbon brush 11, the protruding portion of the rotational shaft element 7a, and the rotation drive device 8. The housing 10 has a substantially cylindrical shape closed at an upper end and opened at the bottom. It is fixed on the wall 1a of the vacuum chamber 1 by a fixing member 17 with an electric insulating member 18 interposed between them. Therefore, the housing 10 and the vacuum chamber 1 are held in electrically insulated state. Thereby, the radio-frequency power and the direct-current power are applied to the carbon brush 11, and the radio-frequency power and the direct-current power are applied to the housing 10 through the rotational shaft element 7a and the cross roller bearing 9. As a result, the vacuum chamber 11 is always kept in electrically grounded state.

Referring now to FIG. 2, the cooling passage of the substrate holder in the ion plating system in the first embodiment of the present invention is specifically described below.

As shown in FIG., grooves 7b and 7c are formed at predetermined positions on the outer periphery of the protruding portion of the rotational shaft element 7a. These grooves 7b and 7c are formed like a ring over the entire circumference of the rotational shaft element 7a. In the upper part and lower part of the grooves 7b and 7c, O-rings 20a to 20c are disposed. These O-rings 20a to 20c are disposed between the rotational shaft element 7a and the housing 10. That is, the grooves 7b and 7c are closed by the O-rings 20a to 20c and the housing 10. Openings are formed in the bottom of the grooves 7b and 7c, and these openings communicate with pipe rings 7d and 7e formed concentrically with the rotation center c. From the pipe rings 7d and 7e, pipes 7f and 7g extend in the radial direction of the rotational shaft element 7a, and these pipes 7f and 7g extend from predetermined positions in the rotational shaft direction of the rotational shaft element 7. The pipes 7f and 7g reach the substrate holder 6a, and are connected to pipe rings 7h and 7i formed concentrically with the rotation center substantially in the center of the substrate holder 6a. Inside the substrate holder 6a, a plurality of cooling pipes 7j are disposed to extend in U-shape in the radial direction of the substrate holder 6. These cooling pipes 7j are provided inside the substrate holder 6a so as to communicate with the pipe rings 7h and 7i. That is, the cooling pipes 7j extend radially from the outer periphery of the pipe ring 7h toward the end portion of the substrate holder 6a, and turn at the end portion of substrate holder 6a to extend in the opposite direction toward the pipe ring 7i so as to be connected to the outer periphery of the pipe ring 7i. In the grooves 7b and 7c formed concentrically with the rotation center c on the outer periphery of the rotational shaft element 7a, a discharge pipe 22 and a supply pipe 23 are disposed in the housing 10 to communicate with the grooves 7b and 7c in order to supply predetermined heat medium used for controlling the temperature of the substrate holder 6a.

As shown in FIG. 2, a connection pipe 24 indicated by solid line is connected to the discharge pipes 2 and a connection pipe 25 indicated by solid line is connected to the supply pipe 23. Further, as shown in FIG. 1, the connection pipe 24 is connected to a three-way valve 26, and two connection pipes extending from the three-way valve 26 are connected to a warm brine tank 29a and a cold brine tank 29b. A liquid feed pump 27 is disposed at a position of the connection pipe 25 extending from the supply pipe 23. The connection pipe 25 is connected to a three-way valve 28. Two connection pipes extending from the three-way valve 28 are connected to the warm brine tank 29a and the cold brine tank 29b. Antifreezing fluid is contained in the warm brine tank 29a and the cold brine tank 29b. In the warm brine tank 29a, the antifreezing fluid is controlled to have a temperature of about 25° C. by a predetermined temperature controller not shown so that the liquid temperature may be about 25° C. In the cold brine tank 29b, the antifreezing fluid is controlled to have a temperature of about −5° C. by a predetermined temperature controller not shown so that the liquid temperature may be about −5° C.

In the ion plating system thus constructed, the operation will be described by referring to FIG. 1 and FIG. 2.

When forming a multi-layered film on the deposition surface of the substrate by using the ion plating system 100, an operator mounts, before depositing the film, the substrate 21a such as a silicon wafer on the substrate mounting surface of the substrate holder 6a by using predetermined fixing member 36. The substrate 21a is mounted on the substrate holder 6a so that the back surface of the substrate 21a may contact the substrate mounting surface of the substrate holder 6a. When mounting the substrate 21a on the substrate holder 6a, in order to prevent moisture in the atmosphere from water condensation on the substrate holder 6a, the three-way valve 26 and the three-way valve 28 are manipulated appropriately to operate the liquid feed pump 27, and the antifreezing fluid (for example, ethylene glycol) contained in the warm brine tank 29a and controlled to have a temperature of about 25° C. is flowed to the connection pipe 25. The antifreezing fluid of about 25° C. supplied to the supply pipe 23 through the connection pipe 25 is first filled into the groove 7c. Then, the antifreezing is filled into the inside of the pipe ring 7e. The antifreezing fluid flows in the pipe 7g and further flows in the plural cooling pipes 7j from the center of the substrate holder 6a toward the end portion. Then, the antifreezing fluid flowing in the cooling pipes 7j from the end portion toward the center in the substrate holder 6a flows in the pipe 7f, and is filled into the pipe ring 7d. The antifreezing fluid filled in the pipe ring 7d is filled into the groove 7b, and flows in the connection pipe 24 through the discharge pipe 22. The antifreezing fluid flowing in the connection pipe 24 is returned to the warm brine tank 29a by the three-way valve 26. Thus, since the substrate holder 6a is warmed by the antifreezing fluid of about 25° C., water condensation due to moisture in the atmosphere can be prevented. After the substrate 21a is mounted on the substrate holder 6a, the inside of the vacuum chamber 1 is evacuated to a predetermined degree of vacuum by operating a predetermined exhaust means not shown. In this case, in order to easily release the gas of the substrate 21a during the evacuation, the antifreezing fluid controlled to have a temperature of about 25° C. is supplied continuously from the warm brine tank 29a toward the substrate holder 6a. As a result, the gas adsorbed on the substrate 21a can be effectively removed. This supply of antifreezing fluid to the substrate holder 6a continues until evacuation is completed. Thereafter, when it is confirmed that the vacuum chamber 1 becomes substantially vacuum, the rotation drive device 8 is operated, and the spur gear 8a is rotated at predetermined speed. As the rotation drive device 8 operates, the spur gear 8a rotates, and by the rotation of the spur gear 8a, the rotational shaft element 7a rotates about the rotation center c. As a result, the substrate holder 6a attached to the lower end of the rotational shaft element 7a rotates, and the substrate 21a rotates about the rotation center c.

Meanwhile, the radio-frequency power source 14 and the direct-current power source 15 are turned on. The radio-frequency power generated by the radio-frequency power source 14 is supplied to the cable 12 through the matching circuit 13 and the direct-current blocking capacitor Co. The direct-current power generated by the direct-current power source 15 is supplied to the cable 12 through the choke coil Lo for radio-frequency blocking. The radio-frequency power and the direct-current power are supplied to the carbon brush 11 through the cable 12. Thus, the radio-frequency power and the direct-current power are supplied to the carbon brush 11, and further are supplied to the current feeding ring 7t in contact with the carbon brush 11. The radio-frequency power and the direct-current power transmitted to the current feeding ring 7t are transmitted to the substrate holder 6a through the conductive rotational shaft element 7a. As a result, the radio-frequency power and the direct-current power are supplied between the substrate holder 6a and the vacuum chamber 1.

Then, in the evaporation sources 2a and 2b, the electron guns are operated, and electron beams are emitted to film materials in the hearths 5a and 5b at predetermined intensity. The film materials are preheated to a predetermined temperature by the energy of emitted electron beams. When diffusing the film materials alternately inside the vacuum chamber 1, the emission intensity of the electron beams emitted from the electron guns in the evaporation sources 2a and 2b are increased alternately, and thereby the film materials in the hearths 5a and 5b are dissolved alternately. At this time, by alternately rotating the rotational shafts 4a and 4b so that only the upper part of the dissolved film materials may be opened, the shutters 3a and 3b are alternately moved above the evaporation sources 2a and 2b. Since the inside of the vacuum chamber 1 is already in substantially vacuum state, the film materials are alternately diffused from the evaporation sources 2a and 2b into the vacuum chamber 1. The diffused film materials are excited by the plasma generated by the radio-frequency power, and the excited film materials are accelerated by the electric field between the substrate holder 6a and vacuum chamber 1 generated by the direct-current power, and are impinged onto and adhered to the surface of the substrate 21a. Hence, dense thin films are formed alternately on the deposition surface of the substrate 21a. That is, the multi-layered thin film comprised of the dense thin films is formed on the deposition surface of the substrate 21a. When forming the multi-layered film, in order to prevent excess temperature rise of substrate 21a due to radiation heat from the evaporation sources 2a and 2b, the three-way valve 28 and the three-way valve 26 are manipulated appropriately, and the liquid feed pump 27 is operated to flow the antifreezing fluid controlled to have a temperature of about −5° C. contained in the cold brine tank 29b into the connection pipe 25 at a predetermined flow rate. Thereby, the antifreezing fluid controlled to have a temperature of about −5° C. is supplied to flow in the pipes 7f and 7g, and the cooling pipes 7j formed inside the rotational shaft element 7a and the substrate holder 6a. That is, the substrate 21a is indirectly cooled by the cooling of the substrate holder 6a by the antifreezing fluid controlled to have a temperature of about −5° C., so that temperature rise can be prevented effectively.

After a predetermined number of layers are formed on the deposition surface of the substrate 21a, atmospheric air is introduced into the vacuum chamber 1 to return it to an atmospheric pressure. At this time, in order to prevent water condensation on the substrate 21a due to the moisture in the atmosphere, the three-way valve 28 and the three-way valve 26 are manipulated appropriately, and the liquid feed pump 27 is operated to flow the antifreezing fluid filled in the warm brine tank 29a and controlled to have a temperature of about 25° C. into the connection pipe 25. As a result, the antifreezing fluid controlled to have a temperature of about 25° C. is supplied to flow in the pipes 7f and 7g, and the cooling pipes 7j formed inside the rotational shaft element 7a and the substrate holder 6a. That is, the substrate 21a is indirectly warmed by warming of the substrate holder 6a by the antifreezing fluid controlled to have a temperature of about 25° C., so that water condensation can be prevented effectively.

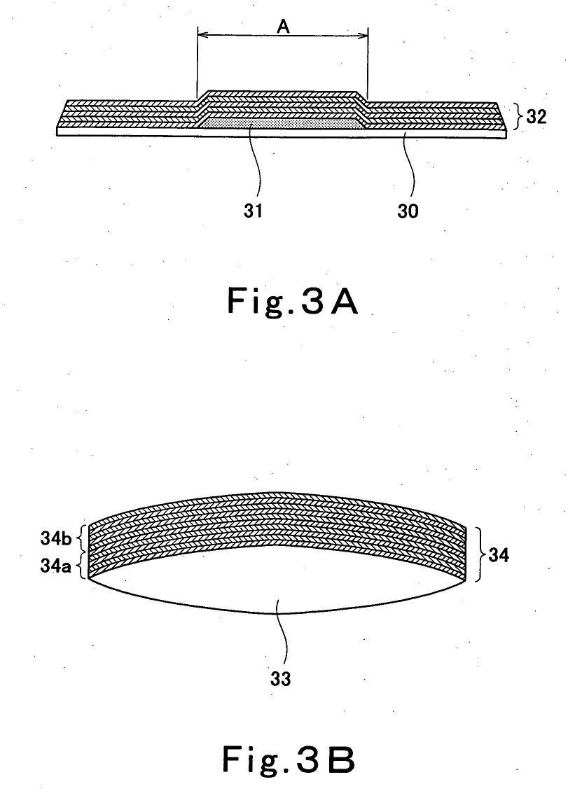

Next, a structure of the multi-layered film formed on the substrate by the above mentioned operation of the ion plating system will be described below by referring to FIG. 3.

FIG. 3A is a schematic sectional view of a structure in which an infrared ray cut filter formed on a silicon wafer.

In FIG. 3A, a silicon wafer 30 has a shape of a flat plate of, for example, 3 to 12 inches in diameter, and 0.3 to 0.6 mm in thickness. In the center region of a principal surface of the silicon wafer 30, a photo resist 31 of a flat plate shape is formed in advance by predetermined manufacturing process. This photo resist 31 is circular to have a maximum diameter A, and its thickness is substantially uniform. The photo resist 31 is formed of thermoplastic polymer resin, and its heat resistant temperature is about 100° C. Therefore, when forming a multi-layered film functioning as infrared ray cut filter on the surface of the silicon wafer 30 and the photo resist 31, it is required to cool the silicon wafer 30 and the photo resist 31 to temperatures to preferably 90° C. or lower. In the embodiment, as mentioned above, the silicon wafer 30 and the photo resist 31 are cooled by flowing the antifreezing fluid controlled to have a temperature of about −5° C. inside the substrate holder 6a. Hence, on the surface of the silicon wafer 30 and the photo resist 31, an infrared ray cut filter 32 is formed. This infrared ray cut filler 32 is comprised of 30 layers or more, or preferably 40 layers or more of two different kinds of thin films with different light transmission characteristics. These two different kinds of films are preferably silicon dioxide and tantalum pentoxide, or silicon dioxide and neodymium pentoxide. Because of a stacked structure as mentioned above, the infrared cut filter 32 functions to block passing of an infrared ray in a predetermined wavelength range. After forming the infrared ray cut filter 32 on the surface of silicon wafer 30 and the photo resist 31, the photo resist 31 is peeled off.

Generally, the optical characteristic (light transmission characteristic) of the infrared ray cut filter 32 varies significantly depending on the number of layers of the infrared ray cut filter. The optical characteristics of the infrared ray cut filters are explained below by referring to the drawings.

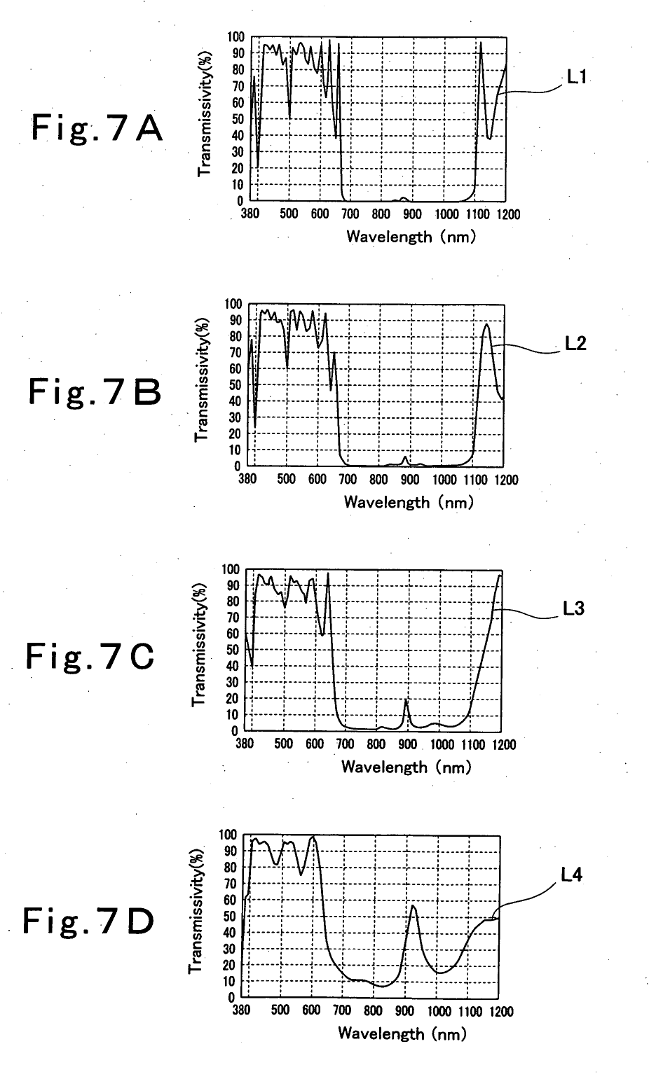

FIGS. 7A to 7D are graphs schematically showing examples of measured data of the optical characteristic (light transmission characteristic) of the infrared ray cut filter. FIG. 7A shows the optical characteristic of the filter comprised of 48 layers, FIG. 7B shows the optical characteristic of the filter comprised of 40 layers, FIG. 7C shows the optical characteristic of the filter comprised of 30 layers, and FIG. 7D shows the optical characteristic of the filter comprised of 16 layers. In the graphs in FIG. 7A to FIG. 7D, the axis of abscissas denotes the wavelength (nm) of light, and the axis of ordinates represents the light transmissivity (%). Here, the examples of measurement of the infrared ray cut filter having the structure shown in FIG. 3 are illustrated.

Typically, an infrared ray is an electromagnetic wave in a wavelength range from the lower limit of about 750 nm at longer wavelength end of visible ray of light to the upper limit of about 1 mm. Therefore, the infrared ray cut filter is strongly required to have an optical characteristic for sharply cutting off the infrared ray in a wavelength range of about 650 nm to 700 nm. The reason is that if using an infrared ray cut filter slowly declining in the transmissivity in a wavelength range of, for example, about 600 nm to 700 nm, the longer wavelength side of the visible ray of light is undesirably cut off due to the effects of the slowing declining transmissivity, and the color balance is worsened visually. As shown by line L4 in FIG. 7D, in the case of the infrared ray cut filter comprised of 16 layers, the inclination of line L4 in the range of 600 nm to 700 nm is moderate, and a specific peak is present near 920 nm. That is, the infrared ray cut filter comprised of 16 layers does not satisfy the above mentioned requirements, and is unable to sufficiently cut the infrared ray with a wavelength of about 920 nm. Therefore, it is judged that the infrared cut filter comprised of 16 layers is hard to use. On the other hand, as shown in FIG. 7C, in the case of the infrared ray cut filter comprised of 30 layers, the optical characteristic L3 is sharply lowered in transmissivity in a wavelength range of about 650 nm to 700 nm, and the transmissivity of about 900 nm is lowered significantly as compared with that shown in FIG. 7D. That is, the optical characteristic of the infrared cut filter comprised of 30 layers satisfies the required optical characteristic demanded of the infrared ray cut filter. Further, the optical characteristics L2 and L1 respectively corresponding to the infrared cut filters comprised of 40 layers and 48 layers are further lowered sharply in the transmissivity in a wavelength range of about 650 nm to 700 nm, and its transmissivity with a wavelength of about 900 nm is further lowered as compared with that of FIG. 7D. That is, the optical characteristics of the infrared cut filters comprised of 48 and 40 layers well satisfy the required optical characteristic of the infrared ray cut filter. Thus, the optical characteristic of the infrared ray cut filter varies significantly depending on the number of layers being stacked. To satisfy sufficiently the required optical characteristic of the infrared ray cut filter, it is necessary to manufacture an infrared ray cut filter comprised of at least 30 stacked layers, preferably 40 stacked layers. Because the infrared ray cut filter 32 shown in FIG. 3A in the embodiment is comprised of 40 layers, it may be very useful as an infrared ray cut filter of excellent optical characteristic.

By using the vacuum film deposition system of the present invention having the construction and configured to operated as described above, the following effects are obtained.

In the present invention, the antifreezing fluid is used as a heat medium for cooling the substrate. By using the antifreezing fluid, the temperature of the substrate holder can be kept below the freezing point (for example, −5° C. or higher to ±0° C. or lower). So, the substrate is indirectly cooled by the antifreezing fluid, and temperature rise of substrate due to radiation heat from the evaporation sources can be effectively prevented. Hence, it is possible to use resin material that is low in heat resistant temperature to form the substrate on which a multi-layered film is deposited. Also, even if the substrate itself is not formed of resin, the present invention is very effective when a resin layer or the like is formed on the substrate as shown in the embodiment. That is, on the substrate having at least the resin layer, 30 or more layers of the infrared ray cut filter is able to be formed. By forming the multi-layered film on the resin, the weight of the optical filter can be significantly reduced. Further, by controlling the temperature of the antifreezing fluid flowing in the passage formed inside the substrate holder in a temperature range of −5° C. or higher to +30° C. or lower, the temperature of the substrate holder can be adjusted in a temperature range of −5° C. or higher to +30° C. or lower. As a result, the temperature of the substrate can be adjusted to have an optimum temperature during film formation. When mounting or dismounting the substrate on or from the substrate holder, by controlling the temperature of the antifreezing fluid in a temperature range of ±0° C. or higher to +30° C. or lower, the temperature of the substrate can be adjusted to be substantially equal to a room temperature. As a result, water condensation on the substrate can be prevented effectively. This becomes very effective means for enhancing the quality of the multi-layered film formed on the deposition surface of substrate. In a time period until the inside of the vacuum chamber is substantially held in vacuum state, by controlling the antifreezing fluid in a temperature range of −0° C. or higher to +30° C. or lower, the temperature of the substrate and substrate holder can be controlled to be substantially equal to the room temperature. So, in the process for evacuating the inside of the vacuum chamber substantially in vacuum state, moisture or the like adsorbed onto the surface of the substrate and the substrate holder can be removed effectively. Also, when forming the multi-layered film on the substrate, the antifreezing fluid used to cool the substrate is flowed into the passage of the substrate holder from the end to the center region of the substrate holder, the end portion of the substrate holder that tends to increase its temperature is efficiently cooled during film depositing process. Since the substrate is cooled by the cooling of the substrate holder in the film depositing process, distortion or deformation of substrate can be prevented, and the optical characteristic of the multi-layered film formed on the deposition surface of the substrate can be improved. In addition, since the vacuum film deposition system of the present invention has grooves on the outer periphery of the rotational shaft, a plurality of holes are formed in the grooves, pipes of predetermined shapes communicate with the plurality of holes, and the pipes are connected to the passages formed inside the substrate holder, the heat medium such as the antifreezing fluid can be supplied to the substrate holder from the periphery of the rotational shaft.

(Second Embodiment)

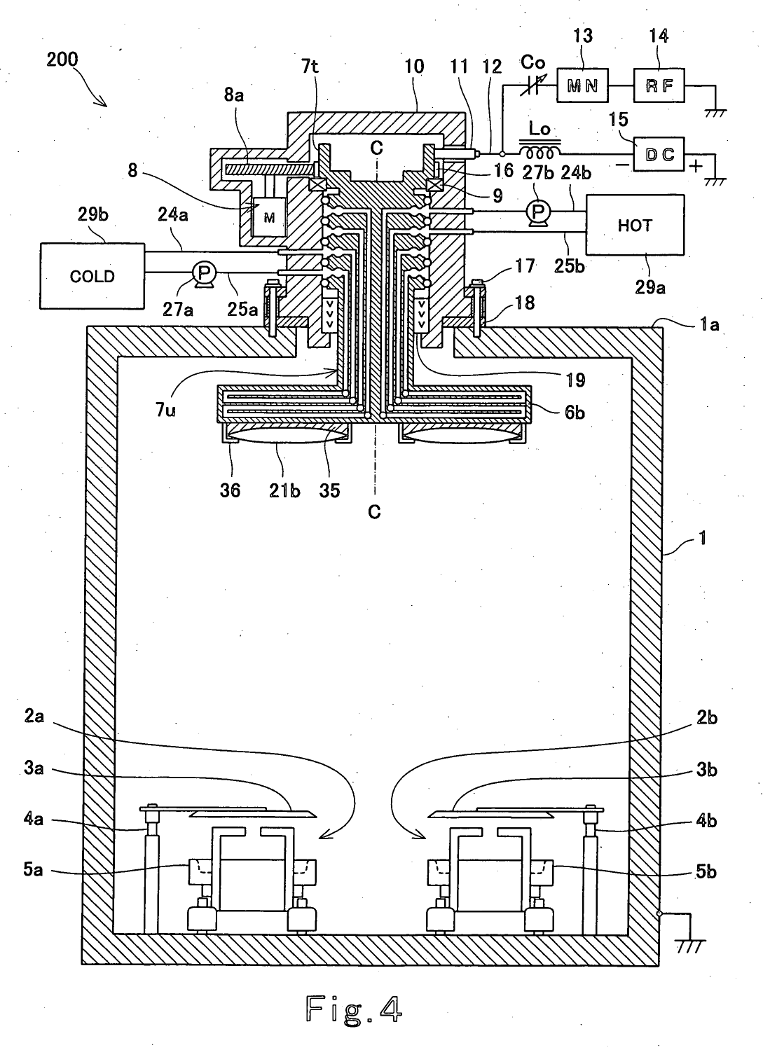

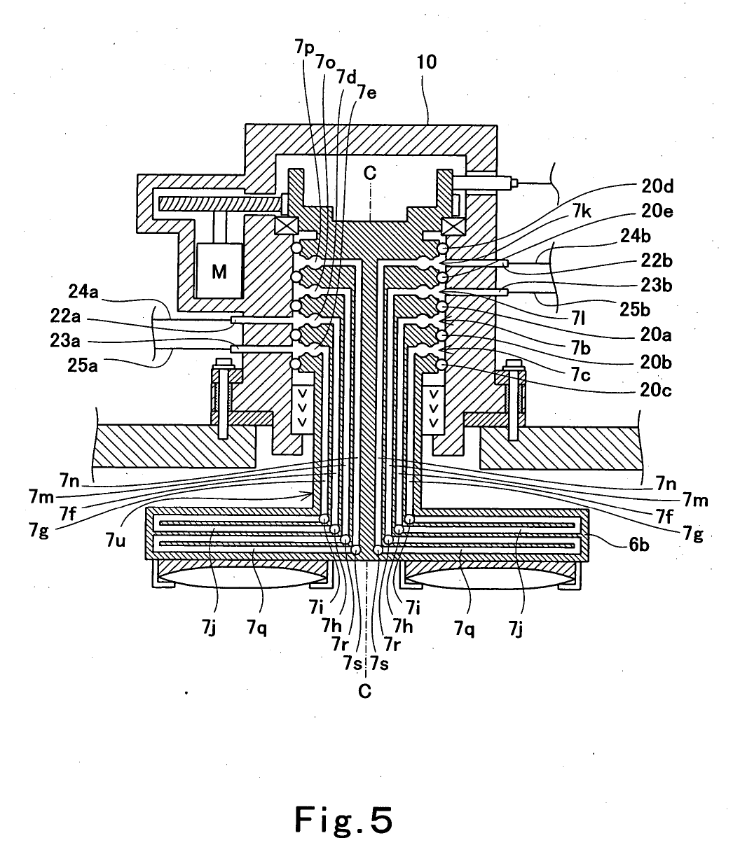

FIG. 4 is a cross-sectional view schematically showing a construction of a vacuum film deposition system in second embodiment of present invention. FIG. 5 is a magnified cross-sectional view schematically showing a rotation drive unit of the vacuum film deposition system shown in FIG. 4. In this embodiment, also, an ion plating system is illustrated as the vacuum deposition system.

Referring first to FIG. 4 and FIG. 5, the structure of the ion plating system in the second embodiment of present invention will be described. The vacuum film deposition system of this embodiment is basically similar to the vacuum film deposition system of the first embodiment, except for the internal structure of the rotational shaft element and the substrate holder, and the feed mechanism of antifreezing fluid. So, explanation of same parts is omitted.

As shown in FIG. 4, as in the first embodiment, the ion plating system 200 comprises the evaporation sources 2a and 2b disposed inside the vacuum chamber 1 made of a conductive material to evaporate film materials. Opposite to the evaporation sources 2a and 2b, a circular substrate holder 6a made of a conductive material is disposed. From the back side of the substrate holder 6b, a rotational shaft element 7u extends. A substrate 21b which is a lens formed of resin is mounted and fixed on the substrate mounting surface of the substrate holder 6b by the fixing member 36 with a heat conductive adapter 35 described below interposed between them. That is, the back surface of the substrate 21b, and the heat conductive adapter 35 and the substrate mounting surface of the substrate holder 6b contact each other. Other structure is the same as that described the first embodiment.

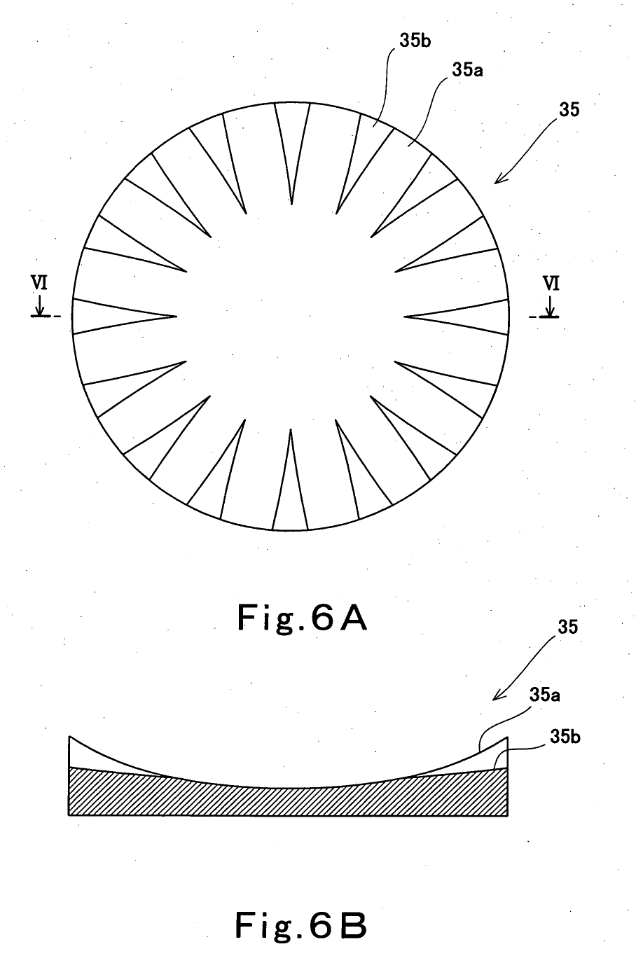

FIGS. 6A and 6B are schematic views of the heat conductive adapter 35, in which FIG. 6A is a plan view thereof, and FIG. 6B is a sectional view along line VI-VI of FIG. 6A.

As shown in FIG. 6A and FIG. 6B, the heat conductive adapter 35 is formed to have a diameter substantially equal to the diameter of the lens mounted thereon. The heat conductive adapter 35 has a curved surface 35a formed according to the radius of curvature of the lens to be mounted thereon, and a stepped part 35b having a predetermined flat surface at a position lower than the curved surface 35a. The stepped part 35b is formed in a taper shape from the outer periphery toward the center of the heat conductive adapter 35 in a plan view, so as not to contact the lens to be mounted thereon. The stepped part 35b is formed in the heat conductive adapter 35 in order to make a uniform in-plane temperature distribution in the transition state of temperature change of the lens to be mounted thereon. For example, in the case where a convex lens is used, because the convex lens is thick in the central part and thin in the peripheral part, its heat capacity decreases from the central part to the peripheral part. Accordingly, by forming the stepped part 35b in the heat conductive adapter 35, the transmission heat from the heat conductive adapter 35 is made less at the peripheral part, and difference in heat capacity in the in-plane temperature distribution of the lens is canceled. Since the curved surface 35a of the heat conductive adapter 35 is formed according to the radius of curvature of the lens to be mounted thereon, the heat conductive adapter 35 is prepared for every kind of lenses to be mounted thereon. The forming material of the heat conductive adapter 35 is not particularly limited as long as it is highly heat conductive. Herein, stainless steel is used for forming the heat conductive adapter 35.

Referring now to FIG. 5, the cooling passage of substrate holder in the ion plating system of the second embodiment of present invention is described specifically below.

As shown in FIG. 5, grooves 7k, 7l, 7b, 7c are formed at predetermined positions on the outer periphery of the protruding portion of the rotational shaft element 7u. These grooves 7k, 7l, 7b, and 7c are formed like rings over the entire circumference of the rotational shaft element 7u. O-rings 20a to 20e are disposed in upper and lower parts of these grooves 7k, 7l, 7b, and 7c. These O-rings 20a to 20e are disposed between the rotational shaft element 7u and the housing 10. That is, the grooves 7k, 7l, 7b, and 7c are closed by the O-rings 20a to 20e and the housing 10. Openings are formed in the bottom of the respective of the grooves 7k, 7l, 7b, and 7c, and communicate with pipe rings 7p, 7o, 7d, and 7e formed concentrically with the rotation center c. From these pipe rings 7p, 7o, 7d, and 7e, pipes 7n, 7m, 7f, and 7g extend in the radial direction of the rotational shaft element 7u. Furthermore, these pipes 7n, 7m, 7f, and 7g extend in the rotational shaft direction of the rotational shaft 7u from predetermined positions. The pipes 7n, 7m, 7f, and 7g reach the substrate holder 6b and are connected to pipe rings 7s, 7r, 7h, and 7i formed concentrically with the rotation center c in substantially the central part. Inside the substrate holder 7b, a plurality of cooling pipes 7j and warming pipes 7q are disposed to extend in U-shape in the radial direction of the substrate holder 6b, and these cooling pipes 7j and the warming pipes 7q are provided inside of the substrate holder 6b so as to communicate with the pipe rings 7s, 7r, 7h, and 7i. That is, the plurality of cooling pipes 7j and the plurality of warming pipes 7q extend radially from the outer peripheries of the pipe rings 7s and 7h toward the end portion of the substrate holder 6b, and further extend in the opposite direction at the end portion of the substrate holder 6b toward the pipe rings 7r and 7i to be connected to the outer peripheries of the pipe rings 7r and 7i. Further, to supply predetermined heat medium used for controlling the temperature of the substrate holder 6b to the grooves 7k, 7l, 7b, and 7c formed concentrically with the rotation center c on the outer periphery of the rotational shaft element 7u, discharge pipes 22a and 23b and supply pipes 23a and 22b are disposed in the housing 10 so as to communicate with the grooves 7k, 7l, 7b, and 7c.

As shown in FIG. 5, connection pipes 24a and 25b indicated by solid line are connected to the discharge pipes 22a and 23b, and connection pipes 25a and 24b indicated by solid line are connected to the supply pipes 23a and 22b. Further, as shown in FIG. 4, the connection pipe 24a and the connection pipe 25a are each connected to the cold brine tank 29b. At a position of the connection pipe 25a, the liquid feed pump 27a is disposed. The connection pipe 24b and the connection pipe 25b are connected to the warm brine tank 29a. At a position of the connection pipe 24b, the liquid feed pump 27b is disposed. Antifreezing fluid is contained in the warm brine tank 29a and the cold brine tank 29b. In the warm brine tank 29a, the antifreezing fluid is controlled to have a temperature of about 25° C. by a predetermined temperature controller not shown. In the cold brine tank 29b, the antifreezing fluid is controlled to have a temperature of about −5° C. by a predetermined temperature controller not shown.

Subsequently, the operation of the ion plating system thus constructed will be described by referring to FIG. 4 and FIG. 5.

When forming a multi-layered film on the deposition surface of the substrate by using the ion plating system 200, the operator mounts, before depositing the film, the substrate 21b which is the resin lens on the substrate mounting surface of the substrate holder 6b by using a predetermined fixing member 36 with the heat conductive adapter 35 interposed between them. In this case, the substrate 21b is mounted on the substrate holder 6b with the heat conductive adapter 35 interposed between them so that the back surface of the substrate 21b may contact the heat conductive adapter 35 and the substrate mounting surface of the substrate holder 6b. When mounting the substrate 21b on the substrate holder 6b, in order to prevent water condensation on the substrate holder 6b due to moisture in the atmosphere, the liquid feed pump 27b is operated to flow the antifreezing fluid controlled to have a temperature of about 25° C. contained in the warm brine tank 29a to the connection pipe 24b. The antifreezing fluid with about 25° C. flowing in the connection pipe 24b and supplied to the supply pipe 22b is first filled into the groove 7k. Then, the antifreezing fluid is supplied into the pipe ring 7p. The antifreezing fluid flows in the pipe 7n and further in the plural cooling pipes 7q from the center of the substrate holder 6b toward the end portion thereof. Then, the antifreezing fluid flows in the cooling pipes 7q from the end portion toward the center portion in the substrate holder 6b and flows in the pipe 7m to be filled into the pipe ring 7o. The antifreezing fluid filled in the pipe ring 7o is filled into the groove 7l, and flows in the connection pipe 25b through the discharge pipe 23b. The antifreezing fluid flowing in the connection pipe 25b is returned to the warm brine tank 29a. Thus, since the substrate holder 6b is warmed by the antifreezing fluid with a temperature of about 25° C., water condensation due to moisture in the atmosphere can be prevented. After the substrate 21b is mounted on the substrate holder 6b, the inside of the vacuum chamber 1 is evacuated to the predetermined degree of vacuum by operating a predetermined exhaust means not shown. During the evacuation, in order to easily release the gas of the substrate 21a, the antifreezing fluid controlled to have a temperature of about 25° C. is supplied continuously from the warm brine tank 29a toward the substrate holder 6b. As a result, the gas adsorbed on the substrate 21b can be effectively removed. This supply of antifreezing fluid to the substrate holder 6b continues until evacuation is completed. When it is confirmed that the vacuum chamber 1 becomes substantially vacuum, the rotation drive device 8 is operated, and the spur gear 8a is rotated at a predetermined speed. As the rotation drive device 8 operates, the spur gear 8a rotates, and by the rotation of the spur gear 8a, the rotational shaft element 7u rotates about the rotation center c. As a result, the substrate holder 6b attached to the lower end of the rotational shaft element 7u rotates, and thereby the substrate 21b rotates about the rotation center c.

The radio-frequency power source 14 and the direct-current power source 15 are turned on. The radio-frequency power generated by the radio-frequency power source 14 is supplied to the cable 12 through the matching circuit 13 and the direct-current blocking capacitor Co. The direct-current power generated by the direct-current power source 15 is supplied to the cable 12 through the choke coil Lo for radio-frequency blocking. The radio-frequency power and the direct-current power are supplied to the carbon brush 11 through the cable 12. The radio-frequency power and the direct-current power are supplied to the carbon brush 11, and further are transmitted to the current feeding ring 7t in contact with the carbon brush 11. The radio-frequency power and the direct-current power transmitted to the current feeding ring 7t are transmitted to the substrate holder 6b through the conductive rotational shaft element 7u.

In the evaporation sources 2a and 2b, the electron guns are operated, and electron beams are emitted to film materials in the hearths 5a and 5b at predetermined intensity. The film materials are preheated to predetermined temperature by the energy of the emitted electron beams. When diffusing the film materials alternately in the vacuum chamber 1, the emission intensity of electron beams emitted from electron guns in the evaporation sources 2a and 2b are increased alternately, and the film materials in the hearths 5a and 5b are dissolved alternately. At this time, by alternately rotating the rotational shafts 4a and 4b so that only the upper part of the dissolved film materials may be opened, the shutters 3a and 3b are alternately moved above the evaporation sources 2a and 2b. Since the inside of the vacuum chamber 1 is already in substantially vacuum state, the film materials are alternately diffused from the evaporation sources 2a and 2b into the vacuum chamber 1. The diffused film materials are excited by the plasma generated by the radio-frequency power, and the excited film materials are accelerated by the electric field between the substrate holder 6b and the vacuum chamber 1 that is generated by the direct-current power, and are impinged onto and adhered to the surface of the substrate 21b. Hence, dense thin films are formed alternately on the deposition surface of the substrate 21b. That is, the multi-layered thin film comprised of the dense thin films is formed on the deposition surface of the substrate 21a. When depositing the multi-layered film, in order to prevent excess temperature rise of substrate 21b due to radiation heat from the evaporation sources 2a and 2b, the liquid feed pump 27a is operated to flow the antifreezing fluid controlled to have a temperature of about −5° C. contained in the cold brine tank 29b into the connection pipe 25a at a predetermined flow rate. Thereby, the antifreezing fluid controlled to have a temperature of about −5° C. is supplied to flow in the pipes 7g formed inside the rotational shaft element 7u, and further flows in the cooling pipes 7j formed inside the substrate holder 6b from the center to the end portion of the substrate holder 6b. The antifreezing fluid reaching the end portion of the substrate holder 6b flows in the opposite direction at the end portion, flows toward the center of the substrate holder 6b, flows in the pipes 7f formed inside the rotational shaft element 7u, and is discharged from the discharge pipe 22a. At this time, the liquid feed pump 27b is operated to flow the antifreezing fluid controlled to have a temperature of about 25° C. contained in the warm brine tank 29a into the supply pipe 22b at a predetermined flow rate. Thereby, the antifreezing fluid controlled to have a temperature of about 25° C. flows in the pipe 7n formed inside the rotational shaft element 7u, and flows in the warming pipe 7q formed inside the rotational shaft element 7u from the center to the end portion of the substrate holder 6b. The antifreezing fluid reaching the end portion of the substrate holder 6b flows in the opposite direction at the end portion, then flows toward the center of the substrate holder 6b, flows in the pipe 7m formed inside the rotational shaft element 8u, and is discharged from the discharge pipe 23b. Thus, in the film deposition process, by supplying cold brine and warm brine to the substrate holder 6b, the substrate 21b is cooled indirectly and uniformly in-plane by cooling of the substrate holder 6b.

As in the first embodiment, after the predetermined multi-layered film is formed on the deposition surface of the substrate 21b, atmospheric air is introduced into the vacuum chamber 1, which is thereby returned to an atmospheric pressure. At this time, to prevent water condensation at the substrate 21b due to the moisture in the atmosphere, the liquid feed pump 27a is stopped and the liquid feed pump 27b is operated to flow the antifreezing fluid controlled to have a temperature of about 25° C. contained in the warm brine tank 29a into the connection pipe 24b. Thereby, the antifreezing fluid controlled to have a temperature of about 25° C. flows in the pipes 7n and 7m and the warming pipes 7q formed inside the rotational shaft element 7u and the substrate holder 6b. That is, since the substrate 21b is warmed indirectly by warming of the substrate holder 6b by the antifreezing fluid controlled to have a temperature of about 25° C., water condensation can be prevented effectively.

A structure of the multi-layered film deposited on the substrate by such operation of the ion plating system will be described below by referring to FIG. 3.

FIG. 3B is a schematic sectional view of a structure in which an infrared ray cut filter is formed on a resin optical lens.

In FIG. 3B, an optical lens 33 has a convex lens shape of, for example, 5 to 40 mm in diameter, and 5 mm to 10 mm in maximum thickness in the center. This optical lens 33 is made of a thermoplastic polymer resin such as Zeonor or Arton, and its heat resistant temperature is about 100° C. Therefore, when forming a multi-layered film functioning as an infrared ray cut filter on the surface of the optical lens 33, the optical lens 33 is required to be cooled preferably to 90° C. or lower. In this embodiment, as described above, the optical lens 33 is cooled by flowing the antifreezing fluid controlled to have a temperature about −5° C. to the inside of the substrate holder 6b. As shown in FIG. 3B, an infrared ray cut filter 34 is formed on the surface of the optical lens 33. This infrared ray cut filler 34 is comprised of a longer wavelength cut filter 34b and a shorter wavelength cut filter 34a. The longer wavelength cut filter 34b and the shorter wavelength cut filter 34a are each structured in such a manner that thin films with different light refractive indices are alternately stacked in 20 layers. That is, this optical lens 33 is provided with the infrared ray cut filter 34 of stacked 40 layers. Since the infrared ray cut filter 34 has a stacked structure having 40 layers, it functions to block transmission of infrared ray in a predetermined wavelength range. As described in the first embodiment, the optical characteristic of the infrared ray cut filter changes significantly-depending on the number of layers to be stacked. For example, as described in FIG. 7, when the infrared ray cut filter is comprised of about 16 layers, sufficient optical characteristic of the infrared ray cut filter is not obtained, and at least 30 layers or more are required to be stacked. The optical lens 33 of the embodiment is provided with the infrared ray cut filter of 40 layers, and therefore functions sufficiently as infrared ray cut filter.

The optical lens 33 of the embodiment is made of acrylic polymer resin. On the surface of the optical lens 33, the infrared ray cut filter of 40 layers is formed. So, the present invention is able to provide an optical lens with the infrared ray cut filter with light weight and excellent optical characteristic. More specifically, the optical lens with the infrared ray cut filter is suitably used in optical systems such as portable video cameras using a CCD element. Typically, the CCD element has the peak of light receiving sensitivity in a infrared ray region. So, by using the optical lens with the infrared ray cut filter, a video image excellent in color balance can be provided. In the conventional optical lens with the infrared ray cut filter, since the infrared ray cut filter is formed on the surface of a glass lens, reduction of weight of portable video camera or the like is impeded by its weight. In contrast, in the optical lens with the infrared ray cut filter of present invention, since the lightweight resin lens is used, the portable video camera or the like can be further reduced in weight. In the embodiment, further, the substrate 21b is mounted on the substrate holder 6b with the heat conductive adapter 35 interposed between them to enhance the heat conduction of the substrate 21b and the substrate holder 6b. By using the heat conductive adapter 35, heat conductivity of the substrate 21b and the substrate holder 6b is improved. As a result, the temperature of the substrate 21b can be controlled easily and efficiently. In the heat conductive adapter 35, a contact area of the heat conductive adapter 35 and the substrate 21b per predetermined area decreases as it is closer to the end portion of the substrate 21b. Because of the shape of the heat conductive adapter 35, the temperature is controlled efficiently at the central part of the substrate 21b, and moderately at the end portion of the substrate 21b. The substrate 21b is slow in temperature change at the central part and fast in temperature change at the end portion because of the influence of its cross-sectional shape. Accordingly, when cooling the substrate 21b, it is possible to make a uniform in-plane temperature distribution in the transition state of temperature change of the substrate 21b.

The present invention is configured as mentioned above, and provides the vacuum film deposition method and system capable of forming a multi-layered film including a number of layers on the deposition surface of the resin substrate or the substrate having at least the resin layer in the surface layer, and an optical filter manufactured by using the same.

In the foregoing description, the ion plating system has been illustrated as the vacuum film deposition system, but it is not limited to the ion plating system in particular. The present invention can be generally carried out in and applied to vacuum film deposition systems for forming a multi-layered film on the resin substrate or on the substrate having the resin layer by mounting the substrate on the substrate holder.

Numerous modifications and alternative embodiments of the present invention will be apparent to those skilled in the art in view of the foregoing description. Accordingly, the description is to be construed as illustrative only, and is provided for the purpose of teaching those skilled in the art the best mode of carrying out the invention. The details of the structure and/or function may be varied substantially without departing from the sprit of the invention.

### INDUSTRIAL APPLICABILITY

A vacuum film deposition method, a system and an optical filter manufactured by using the same of present invention are useful as the vacuum film deposition method, the system and the optical filter capable of forming a multi-layered film a deposition surface of a resin substrate or a substrate having at least a resin layer in a surface layer.

1. A vacuum film deposition method comprising the steps of:
mounting a substrate on a substrate holder that is disposed in a vacuum chamber and is provided with a passage in which a predetermined heat medium flows;
maintaining an inside of the vacuum chamber substantially in vacuum state;
evaporating evaporation materials from two or more evaporation sources in the inside of the vacuum chamber;
diffusing the evaporated evaporation materials in the inside of the vacuum chamber in a predetermined order; and
depositing the diffused evaporation materials on a deposition surface of the substrate, thereby forming a multi-layered film made of the evaporation materials on the deposition surface of the substrate;
wherein an antifreezing fluid is used as the predetermined heat medium flowing in the passage of the substrate holder.

2. The vacuum film deposition method according to claim 1, wherein the antifreezing fluid used as the predetermined heat medium is controlled to have a temperature in a temperature range of −5° C. or higher to +30° C. or lower.

3. The vacuum film deposition method according to claim 2, wherein the antifreezing fluid used as the predetermined heat medium when mounting or dismounting the substrate on or from the substrate holder is controlled to have a temperature in a temperature range of ±0° C. or higher to +30° C. or lower.

4. The vacuum film deposition method according to claim 2, wherein the antifreezing fluid used as the predetermined heat medium in a period until the inside of the vacuum chamber is held substantially in the vacuum state is controlled to have a temperature in a temperature range of ±0° C. or higher to +30° C. or lower.

5. The vacuum film deposition method according to claim 2, wherein the antifreezing fluid used as the predetermined heat medium when depositing the multi-layered film on the deposition surface of the substrate in the inside of the vacuum chamber is controlled to have a temperature in a temperature range of −5° C. or higher to −0° C. or lower.

6. A vacuum film deposition method comprising the steps of:
mounting a substrate on a substrate holder that is disposed in a vacuum chamber and is provided with a passage in which predetermined heat medium flows;
maintaining an inside of the vacuum chamber substantially in vacuum state;
evaporating evaporation materials from two or more evaporation sources in the inside of the vacuum chamber;
diffusing the evaporated evaporation materials in the inside of the vacuum chamber in a predetermined order; and
depositing the diffused evaporation materials on a deposition surface of the substrate, thereby forming a multi-layered film made of the evaporation materials on the deposition surface of the substrate; wherein the passage includes one passages and opposite passages that are arranged radially, and the multi-layered film is formed on the deposition surface of the substrate while flowing the predetermined heat medium into the one passage from an end portion of the substrate holder toward a center portion of the substrate holder, and flowing the predetermined heat medium into the opposite passage from the center portion of the substrate holder toward the end portion of the substrate holder.

7. A vacuum film deposition system comprising:
a vacuum chamber that maintains an inside thereof substantially in vacuum state;
a rotational shaft rotatably penetrating through the vacuum chamber;
a heat medium supply unit connected to a heat medium supply passage in which a predetermined heat medium flows;
a substrate holder fixed to an end portion of the rotational shaft, for holding the substrate having the passage in which the predetermined heat medium flows; and
two or more evaporation sources including evaporation materials deposited to form a multi-layered film on a deposition surface of the substrate held on the substrate holder;
wherein the rotational shaft has a groove formed to extend over an entire circumference of an outer periphery, the groove is connected to the passage of the substrate holder through a plurality of holes, and the groove is maintained in a sealed state with respect to the heat medium supply unit by a predetermined seal means.

8. The vacuum film deposition system according to claim 7, further comprising:
a tubular housing for accommodating a region of the rotational shaft in which the groove is provided;
wherein a penetrating hole forming the heat medium supply unit is formed in a region of an inner peripheral surface of the housing that corresponds to the groove of the rotational shaft,
and wherein a seal member is disposed between the housing and the rotational shaft, and the groove is maintained in a sealed state with respect to the penetrating hole by the seal member.

9. A vacuum film deposition method comprising the steps of:
mounting a substrate on a substrate holder that is disposed in a vacuum chamber;
maintaining an inside of the vacuum chamber substantially in vacuum state;
evaporating evaporation materials from two or more evaporation sources in the inside of the vacuum chamber;
diffusing the evaporated evaporation materials in the inside of the vacuum chamber in a predetermined order; and
depositing the diffused evaporation materials on a deposition surface of the substrate, thereby forming a multi-layered film made of the evaporation materials on the deposition surface of the substrate;
wherein the multi-layered film is formed on the substrate mounted on the substrate holder with a heat conductive adapter interposed between the substrate and the substrate holder.

10. The vacuum film deposition method according to claim 9, wherein the substrate has a thickness that decreases in a direction from one region thereof toward an opposite region thereof, and a contact area of the heat conductive adapter and the substrate per predetermined area decreases according to a decrease in the thickness of the substrate in the direction from the one region thereof toward the opposite region thereof.

11. A vacuum film deposition system comprising:
a vacuum chamber that maintains an inside thereof substantially in vacuum state;
a substrate holder for holding a substrate in the inside of the vacuum chamber; and
two or more evaporation sources including evaporation materials deposited to form a multi-layered film on a deposition surface of the substrate held on the substrate holder;
wherein a heat conductive adapter for increasing heat conductivity between the substrate and substrate holder is disposed on a surface of the substrate holder on which the substrate is held.

12. An optical filter comprising a resin layer in at least a surface layer of a substrate, and two types of thin films with different light refractive indices that are alternately stacked on the resin layer to form an alternate layer,
wherein the alternate layer is comprised of the films of at least 30 layers.

13. A vacuum film deposition system comprising:
a vacuum chamber that maintains an inside thereof in substantially vacuum state;
a substrate holder that holds a substrate in the inside of the vacuum chamber and is provided with a passage in which a predetermined heat medium flows; and
an evaporation source including an evaporation material deposited to form a film on a deposition surface of the substrate held on the substrate holder;
wherein the passage includes one passages radially arranged to flow the predetermined heat medium from an end portion of the substrate holder to a center portion of the substrate holder, and opposite passages radially arranged to flow the predetermined heat medium from the center portion of the substrate holder to the end portion of the substrate holder.
